(19) United States
(12) Patent Application Publication
(10) Pub. No.: US 2026/0165104 A1
(43) Pub. Date: Jun. 11, 2026

(54) SELECTIVELY ENLARGING A VIA THROUGH A DIRECTIONAL ION BEAM PROCESS

(71) Applicant: Taiwan Semiconductor Manufacturing Company, Ltd., Hsin-Chu (TW)

(72) Inventors: Wan-Yi Lin, Hsinchu (TW); Yu-Hsiang Chen, Hsinchu City (TW); Cai-Ling Wu, Hsinchu (TW); Hsiu-Wen Hsueh, Taichung City (TW); Po-Hsiang Huang, Taipei City (TW); Wei-Ting Chien, Hsinchu City (TW)

(21) Appl. No.: 19/086,830

(22) Filed: Mar. 21, 2025

Related U.S. Application Data
(60) Provisional application No. 63/728,958, filed on Dec. 6, 2024.

(51) Int. Cl. H01L 21/768; H01L 21/033; H01L 21/311; H01L 23/522; H01L 23/528

(52) U.S. Cl. CPC H10W 20/089; H10P 50/73; H10P 76/405; H10P 76/4085; H10W 20/056; H10W 20/063; H10W 20/42; H10W 20/435

(57) ABSTRACT

A mask layer is formed over a dielectric structure. The mask layer includes an opening that exposes a portion of the dielectric structure. A protective layer is formed on the mask layer. The protective layer covers at least side surfaces of the opening. After the forming of the protective layer, a directional etching process is performed to the mask layer. The directional etching process is performed in a first direction, while the protective layer protects the mask layer from being etched in a second direction different from the first direction, such that the opening is enlarged in the first direction without being substantially affected in the second direction after the directional etching process has been performed. The opening is extended vertically into the dielectric structure after the opening has been enlarged in the first direction. A conductive via is formed in the opening.

### PRIORITY DATA

The present application is a Utility Patent Application of Provisional U.S. patent application Ser. No. 63/728,958, filed on Dec. 6, 2024, entitled “VIA TWO DIMENSIONAL EXPANSION THROUGH ION BEAM IMPLEMENTATION”, the disclosure of which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, such scaling down has also increased the complexity of processing and manufacturing ICs. For example, as device sizes shrink, there may be a pitch shrinkage in the interconnect structure, which may in turn increase the resistance of vias. As a result, IC device power efficiency and/or speed may be degraded.

Therefore, although conventional methods of fabricating semiconductor devices have generally been adequate, they have not been satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a perspective view of an IC device in the form of a FinFET according to various aspects of the present disclosure.

FIG. 1B is a planar top view of an IC device in the form of a FinFET according to various aspects of the present disclosure.

FIG. 1C is a cross-sectional side view of an IC device in the form of a GAA device according to various aspects of the present disclosure.

FIGS. 2A and 2B are a cross-sectional side view and a top view illustrating an IC device at a stage of fabrication according to various aspects of the present disclosure.

FIGS. 3A and 3B are a cross-sectional side view and a top view illustrating an IC device at a stage of fabrication according to various aspects of the present disclosure.

FIGS. 4A and 4B are a cross-sectional side view and a top view illustrating an IC device at a stage of fabrication according to various aspects of the present disclosure.

FIGS. 5A-5C are diagrammatic views illustrating a directional push process according to various aspects of the present disclosure.

FIGS. 6A-6B and 6C are cross-sectional side views and a top view illustrating an IC device at a stage of fabrication according to various aspects of the present disclosure.

FIGS. 7A and 7B are a cross-sectional side view and a top view illustrating an IC device at a stage of fabrication according to various aspects of the present disclosure.

FIGS. 8A and 8B are a cross-sectional side view and a top view illustrating an IC device at a stage of fabrication according to various aspects of the present disclosure.

FIG. 9 is a top view illustrating an IC device at a stage of fabrication according to various aspects of the present disclosure.

FIG. 10 is a cross-sectional side view illustrating an IC device at a stage of fabrication according to various aspects of the present disclosure.

FIGS. 11-12 are cross-sectional side views illustrating an IC device according to various aspects of the present disclosure.

FIG. 13 is a block diagram of a manufacturing system according to various aspects of the present disclosure.

FIG. 14 is a flowchart illustrating a method of fabricating an IC device according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc., as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to semiconductor devices, and more particularly to field-effect transistors (FETs), such as three-dimensional fin-shaped FETs (FinFETs) or gate-all-around (GAA) devices. In that regard, a FinFET device is a fin-like field-effect transistor device, and a GAA device is a multi-channel field-effect transistor device. FinFET devices and GAA devices have both been gaining popularity recently in the semiconductor industry, since they offer several advantages over traditional Metal-Oxide Semiconductor Field Effect Transistor (MOSFET) devices (e.g., “planar” transistor devices). These advantages may include better chip area efficiency, improved carrier mobility, and fabrication processing that is compatible with the fabrication processing of planar devices. Thus, it may be desirable to design an integrated circuit (IC) chip using FinFET devices or GAA devices for a portion of, or the entire IC chip.

However, in spite of the advantages offered by the FinFET devices and/or GAA devices, certain challenges may still remain in IC applications in which FinFET or GAA devices are implemented. For instance, interconnect structures may be formed on ICs to provide electrical routing and/or connectivity to the various IC components, including the FinFET and/or GAA devices. The interconnect structures may include multiple interconnect layers, where each interconnect layer includes a plurality of interconnection elements (e.g., metal lines), and the interconnection elements from different interconnect layers are interconnected together by a plurality of conductive vias. However, as device sizes get scaled down, so does the size of the conductive vias and/or the interconnection elements, which may in turn increase a parasitic resistance associated with the conductive vias may increase. If lithography processes or optical proximity correction (OPC) features are used to increase the critical dimension (CD) of the conductive vias, that may elevate a bridging (e.g., electrical shorting) risk between adjacently located conductive devices, while the incremental CD boost may be small (e.g., 3 nanometers (nm)). There may also be issues pertaining to controllability, which may further increase electrical bridging risks (e.g., a tiger-tooth type of electrical shorting issue).

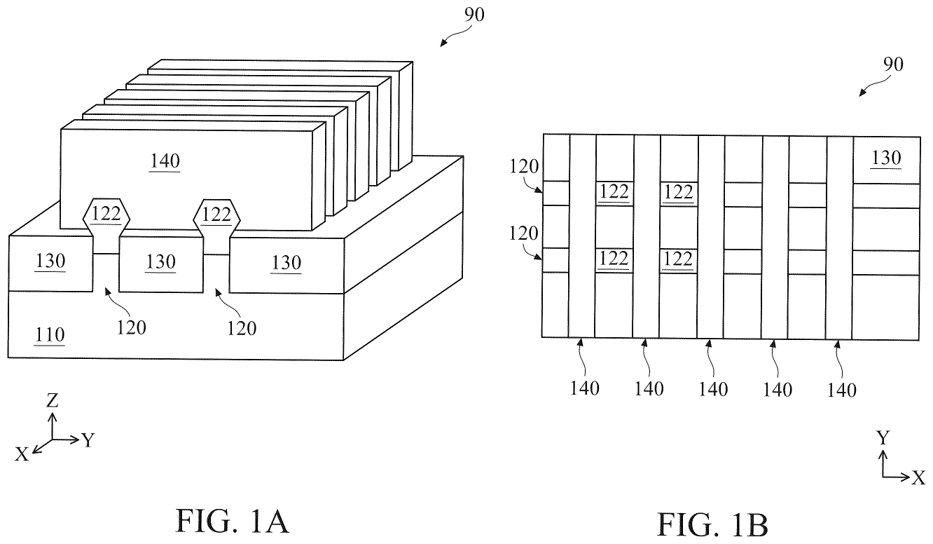

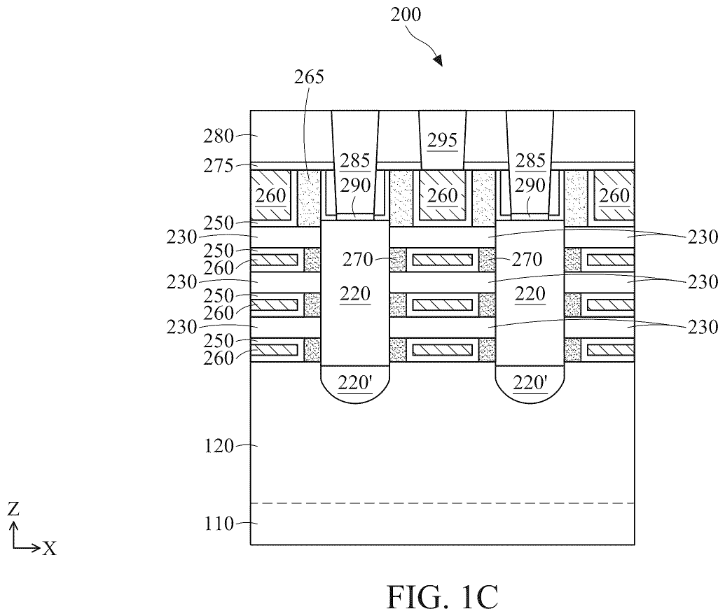

To address these challenges discussed above, the present disclosure implements a protection layer (e.g., a low temperature oxide (LTO)) over a photoresist layer and performs a directional ion beam process after the photolithography process, which may enlarge a conductive via in a first horizontal direction but in a second horizontal direction. The overall surface area increase of the conductive via (e.g., due to it being enlarged in the first horizontal direction) may lead to a reduction in its parasitic resistance, which translates into improvements in IC performance and/or yield. Meanwhile, the fact that the size of the conductive via remains relatively the same in the second horizontal direction may minimize the potential electrical bridging risks associated with the conductive via. In other words, the present application can achieve parasitic resistance reduction without elevating electrical bridging risks. The various aspects of the present disclosure will now be discussed in greater detail with reference to FIGS. 1A-1C, 2A-2B, 3A-3B, 4A-4B, 5A-5C, 6A-6C, 7A-7B, 8A-8B, and 9-14.

FIGS. 1A-1C describe the basic structures of example FinFET and GAA devices. Referring now to FIGS. 1A and 1B, a three-dimensional perspective view and a top view of a portion of an Integrated Circuit (IC) device 90 are illustrated, respectively. The IC device 90 may be an intermediate device fabricated during processing of an IC, or a portion thereof, that may comprise static random-access memory (SRAM) and/or other logic circuits, passive components such as resistors, capacitors, and inductors, and active components such as p-type FETs (PFETs), n-type FETs (NFETs), FinFETs, metal-oxide semiconductor field effect transistors (MOSFET), complementary metal-oxide semiconductor (CMOS) transistors, bipolar transistors, high voltage transistors, high frequency transistors, and/or other memory cells. The present disclosure is not limited to any particular number of devices or device regions, or to any particular device configurations, unless otherwise claimed. For example, although the IC device 90 as illustrated is a three-dimensional FinFET device, the concepts of the present disclosure may also apply to planar FET devices or GAA devices.

Referring to FIG. 1A, the IC device 90 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions 120 are formed on the substrate 110. The active regions 120 are elongated fin-like structures that protrude upwardly out of the substrate 110. As such, the active regions 120 may be interchangeably referred to as fin structures 120 hereinafter. In the case of Gate-All-Around (GAA) devices, however, the active region may include the channel formed over (or above) the fin base/mesa, but does not include the fin base/mesa itself. Rather, as will be discussed in more detail below, the active regions of GAA devices comprise nano-structures, such as nano-sheets. In any case, the fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 90 also includes source/drain features 122 formed over the fin structures 120. The source/drain features 122 may include epi-layers that are epitaxially grown on the fin structures 120. The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fin structures 120 on three sides of each of the fin structures 120. The gate structures 140 may be dummy gate structures (e.g., containing an oxide gate dielectric and a polysilicon gate electrode), or they may be HKMG structures that contain a high-k gate dielectric and a metal gate electrode, where the HKMG structures are formed by replacing the dummy gate structures. Though not depicted herein, the gate structure 140 may include additional material layers, such as an interfacial layer over the fin structures 120, a capping layer, other suitable layers, or combinations thereof.

Referring to FIG. 1B, multiple fin structures 120 are oriented lengthwise along the X-direction, and multiple gate structures 140 are oriented lengthwise along the Y-direction, i.e., generally perpendicular to the fin structures 120. In many embodiments, the IC device 90 includes additional features such as gate spacers disposed along sidewalls of the gate structures 140, hard mask layer(s) disposed over the gate structures 140, and numerous other features.

FIG. 1C illustrates a diagrammatic cross-sectional side view of a portion of an IC device 200 fabricated according to embodiments of the present disclosure, where the IC device 200 is a gate-all-around (GAA) device and may be referred to as a GAA device 200 hereinafter. It is understood that the GAA device 200 may be an NFET in some embodiments, or it may be a PFET in other embodiments.

Referring to FIG. 1C, the cross-sectional view of the GAA device 200 is taken along an X-Z plane, where the X-direction (same X-direction as in FIG. 1A) is the horizontal direction, and the Z-direction (same Z-direction as in FIG. 1A) is the vertical direction. The GAA device 200 includes a substrate 110 and a vertically raised fin structure 120 protruding out of the substrate 110, which may be similar to the fin structure 120 discussed above. In some embodiments, the fin structure 210 includes a semiconductor material, such as silicon. The GAA device 200 includes source/drain features 220, which may be similar to the source/drain features 122 discussed above. Note that source/drain features 220 may refer to a source or a drain, individually or collectively dependent upon the context. The source/drain features 220 are formed over the fin structures 120, and a portion 220′ of each of the source/drain features 220 may protrude downwardly (in the Z-direction) into the fin structure 120. In embodiments where the GAA device 200 is an NFET, the source/drain features 220 include silicon phosphorous (SiP). In embodiments where the GAA device 200 is a PFET, the source/drain features 220 include silicon germanium (SiGe).

The GAA device 200 includes a plurality of channels, for example channels 230 as shown in FIG. 1C. The channels 230 each include a semiconductive material, for example silicon or a silicon compound. The channels 230 are nanostructures (e.g., having sizes that are in a range of a few nanometers) and may also each have an elongated shape and extend in the X-direction. In some embodiments, the channels 230 may each have a nano-wire shape, a nano-sheet shape, a nano-tube shape, etc. The cross-sectional profile of the nano-wire, nano-sheet, or nano-tube may be round/circular, square, rectangular, hexagonal, elliptical, or combinations thereof.

In some embodiments, the lengths (e.g., measured in the X-direction) of the channels 230 may be different from each other. For example, a length of one of the channels 230 may be less than a length of another one of the channels 230. In some embodiments, each of the channels 230 may have a different thickness.

In some embodiments, a spacing (e.g., measured in the Z-direction) between the channels 230 (each channel from adjacent channels) is in a range between about 2 nanometers (nm) and about 12 nm. In some embodiments, a thickness (e.g., measured in the Z-direction) of each of the channels 230 is in a range between about 5 nm and about 2 nm. In some embodiments, a width (e.g., measured in the Y-direction of FIG. 1A) of each of the channels 230 is in a range between about 15 nm and about 150 nm. A plurality of interfacial layers (ILs) may also be formed on the upper and lower surfaces of the channels 230.

The GAA device 200 also includes gate structures that are disposed over and in between the channels 230. The gate structures may include gate dielectric layers 250. In some embodiments, the gate dielectric layers 250 include a high-k gate dielectric. The gate structures further include one or more metal gate electrodes 260. The metal gate electrodes may include work function metal layers. In embodiments where the GAA device 200 is an NFET, the one or more work function metal layers include N-type work function metal layers, such as TiAlC. In embodiments where the GAA device 200 is a PFET, the one or more work function metal layers include P-type work function metal layers, such as TiN.

The metal gate electrodes also include fill metals. In the portion of the gate structure formed over the channels 230, the fill metals are formed over the one or more work function metal layers. In some embodiments, the one or more work function metal layers may have a U-shape and wrap around the fill metal, and the gate dielectric layer 250 may also have a U-shape and wrap around the one or more work function metal layers. In portions of the gate structures formed between the channels 230, the fill metal is circumferentially surrounded (in the cross-sectional view) by the one or more work function metal layers, which is then circumferentially surrounded by the gate dielectric layer 250. It is understood that the gate structures may also include a glue layer that is formed between the one or more work function metal layers and the fill metal to increase adhesion. However, for reasons of simplicity, such a glue layer is not specifically illustrated herein.

The GAA device 200 also includes gate spacers 265 and inner spacers 270 that are disposed on sidewalls of the gate dielectric layer 250. The inner spacers 270 are also disposed between the channels 230. The gate spacers and the inner spacers 270 may include a dielectric material, for example a low-k material such as SiOCN, SiON, SiN, or SiOC.

Additional dielectric layers, such as dielectric layers 275 and 280, may be formed over the gate electrodes 260 and gate spacers 265. As non-limiting examples, these dielectric layers may include interlayer dielectric (ILD), mask layers, or etching-stop layers. Conductive vias or conducts of the GAA devices 200 may be formed to extend vertically through these dielectric layers 275 and 280, to provide electrical connectivity to the components of the GAA device. For example, the GAA device 200 may include source/drain contacts 285285 that are formed over the source/drain features 220. The source/drain contacts 285 may include a conductive material such as cobalt, copper, aluminum, tungsten, or combinations thereof. The source/drain contacts 285 are surrounded by one or more layers, such as barrier layers, which help prevent or reduce diffusion of materials from and into the source/drain contacts 285. In some embodiments, the barrier layer includes TiN, and the barrier layer includes SiN. A silicide layer 290 may also be formed between the source/drain features 220 and the source/drain contacts 285, so as to reduce the source/drain contact resistance. The silicide layer 290 may contain a metal silicide material, such as cobalt silicide in some embodiments. Similarly, a gate contact 295 is formed over one of the gate electrodes 260 to establish electrical connectivity to the gate structure. The gate contact 295 may contain similar conductive materials as the source/drain contacts 285 in some embodiments.

Regardless of whether the transistors of an IC are implemented as a FinFET of FIGS. 1A-1B or a GAA device of FIG. 1C, it is understood that they may benefit from the concepts of the present disclosure, as discussed below in more detail.

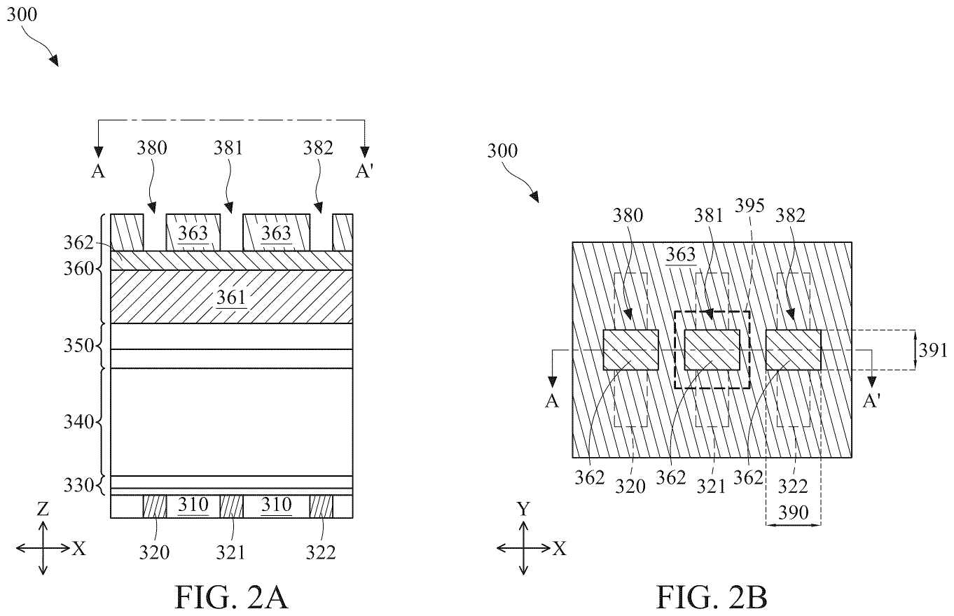

FIGS. 2A and 2B are a diagrammatic fragmentary cross-sectional side view and a diagrammatic fragmentary planar top view, respectively, of an IC device 300 at a particular stage of fabrication according to embodiments of the present disclosure. The cross-sectional side view of FIG. 2A is taken along a vertical plane defined by an X-direction horizontally and a Z-direction vertically. The planar top view of FIG. 2B is taken along a horizontally plane defined by the X-direction and a Y-direction horizontally. A cutline A-A′ shown in FIG. 2A corresponds to the location in the top view of FIG. 2B where the cross-sectional view of FIG. 2A is taken. It is understood that the X-direction, the Y-direction, and the Z-direction are orthogonal or perpendicular to one another.

The IC device 300 includes a dielectric structure 310. The dielectric structure 310 may include silicon oxide, silicon oxynitride, silicon nitride, silicon carbide, or a low-k dielectric material having a dielectric constant lower than that of silicon oxide (e.g., less about 3.9). As non-limiting examples, the low-k dielectric material may include a carbon-containing low-k dielectric material, Hydrogen SilsesQuioxane (HSQ), MethylSilsesQuioxane (MSQ), or the like. The dielectric structure 310 may be formed via one or more deposition processes, such as chemical vapor deposition (CVD), physical vapor deposition (PVD), atomic layer deposition (ALD), or combinations thereof.

The dielectric structure 310 may be a part of a multi-layer interconnect (MLI) structure that is formed over a substrate (e.g., over the substrate 110 discussed above). The MLI structure includes a plurality of interconnect layers (e.g., M₀ through M_{N}), as well as a plurality of conductive vias that interconnect the various interconnect layers together. The interconnect layers may include a plurality of interconnection elements 320-322, which may be implemented as metal lines (e.g., elongated conductive strips that contain copper, aluminum, tungsten, tantalum, cobalt, ruthenium, or another type of suitable conductive material). It is understood that although the interconnection elements 320-322 are not directly visible in the planar top view of FIG. 2B, their respective locations are still illustrated as dashed contours in FIG. 2B to facilitate the understanding of the present disclosure. In any case, the interconnection elements 320-322 (along with other interconnection elements not illustrated herein) are configured to route electrical signals, and the interconnection elements from different interconnect layers are interconnected together by the conductive vias. As discussed above, various aspects of the present disclosure pertains to an improved scheme for forming the conductive vias such that the conductive vias can achieve a parasitic resistance reduction without elevating the electrical shorting risks.

The IC device 300 further includes an etching-stop layer 330 formed over the dielectric structure 310, a low-k film 340 formed over the etching-stop layer 330, a mask layer 350 formed over the low-k film 340, and another mask layer 360 formed over the mask layer 350. In various embodiments, the etching-stop layer 330, the low-k film 340, and the mask layer 350 may include dielectric materials, but the type of dielectric material included in these layers 330-350 may be different. For example, the low-k film 340 may include a low-k dielectric material having a dielectric constant less than about 3.9, but the etching-stop layer 330 and the mask layer 350 may include non-low-k type of dielectric materials. The mask layer 360 may include a photo-sensitive material. For example, the mask layer 360 may include a tri-layer photoresist, which may include a bottom layer 361, a middle layer 362, and a top layer 363. In some embodiments, the bottom layer may have a thickness (in the vertical Z-direction) in a range between about 1500 angstroms and about 2500 angstroms, the middle layer may have a thickness (in the vertical Z-direction) in a range between about 300 angstroms and about 400 angstroms, and the top layer may have a thickness (in the vertical Z-direction) in a range between about 1000 angstroms and about 1500 angstroms.

A photolithography process is performed to pattern the mask layer 360. For example, the top layer 363 of the tri-layer photoresist is patterned to form a plurality of openings, such as openings 380, 381, and 382. The openings 380, 381, and 382 may be vertically aligned with the interconnection elements 320, 321, and 322, respectively, since the openings 380-382 will be used to define via openings (in which conductive vias will be formed) directly over the interconnection elements 320-322. Each of these openings 380-382 may have a dimension 390 in the X-direction and a dimension 391 in the Y-direction at this stage of fabrication.

FIG. 2B also illustrates a dashed box 395. This dashed box 395 represents what the size of the via openings (e.g., by the time the opening 381 is extended through the low-k film 340 and the etching-stop layer 330 to become the via opening) could have been, if the fabrication processes of the present disclosure are not performed. Such an opening (represented by the dashed box 395) may cause the subsequently formed conductive via (by filling the opening with a conductive material) to be located too close to other adjacently located conductive vias as well, which may elevate an electrical shorting risk. To address this potential issue, the present disclosure implements a directional push to enlarge the via opening in the Y-direction but not in the X-direction, as will be discussed below in more detail.

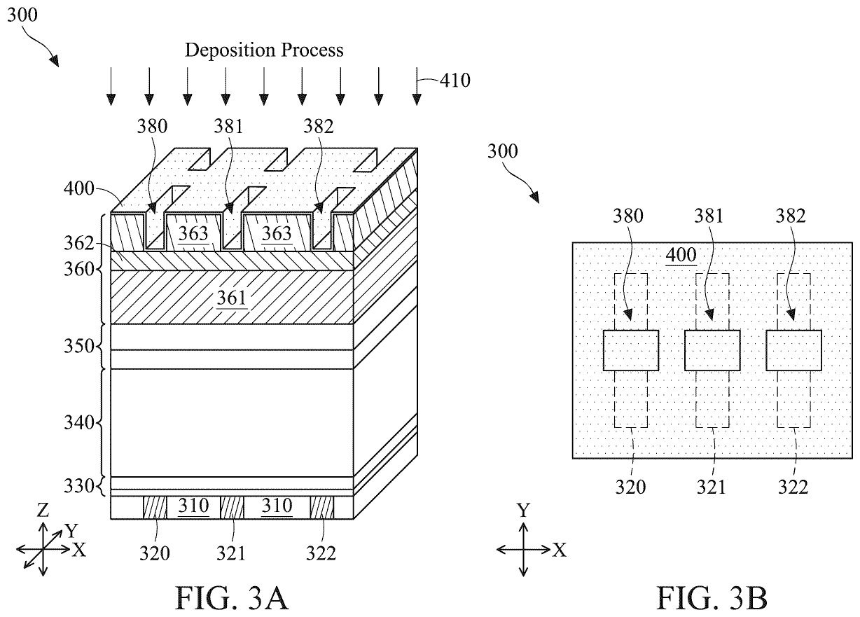

Referring now to FIGS. 3A and 3B, a diagrammatic fragmentary three-dimensional perspective view and a diagrammatic fragmentary planar top view of the IC device 300 are illustrated, respectively, at a stage of fabrication subsequent to the stage of fabrication illustrated in FIGS. 2A-2B. A protective layer 400 is formed over the mask layer 360 by a deposition process 410. In some embodiments, the deposition process 410 includes an atomic layer deposition (ALD) process. In other embodiments, the deposition process 410 may utilize a different suitable deposition technique to form the protective layer 400. In some embodiments, the protective layer 400 includes a dielectric material, such as silicon oxide (SiO₂) (e.g., low-temperature oxide, or LTO). In other embodiments, the protective layer 400 includes aluminum oxide (AlₓO_{y}) or tin oxide (SnO_{y}). In some embodiments, the protective layer 400 has a thickness in a range between about 5 angstroms and about 15 angstroms.

Regardless of the specific details of the deposition process 410 or its specific material composition, the protective layer 400 is deposited directly onto the exposed surfaces of the top layer 363 and the middle layer 362 of the mask layer 360. For example, the protective layer 400 is deposited onto the top surfaces of the middle layer 362 that are exposed by the openings 380-382, as well as onto the side surfaces (e.g., the side surfaces facing the X-direction as well as the side surfaces facing the Y-direction) of the top layer 363 that are exposed by the openings 380-382. The protective layer 400 is also deposited onto the top surface of the top layer 363. As will be explained in more detail below, the protective layer 400 is formed according to the present disclosure to facilitate the directional push of the openings 380-382 in a subsequent process.

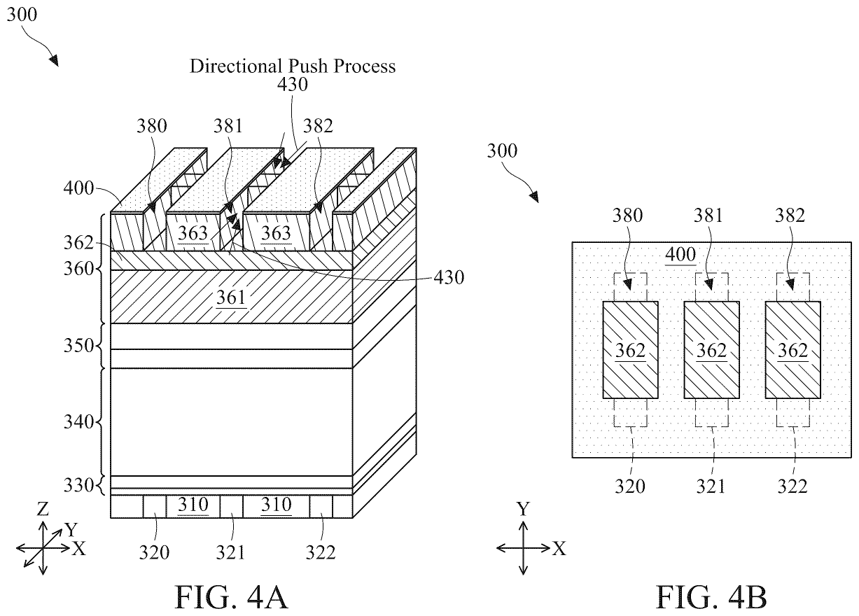

Referring now to FIGS. 4A and 4B, a diagrammatic fragmentary three-dimensional perspective view and a diagrammatic fragmentary planar top view of the IC device 300 are illustrated, respectively, at a stage of fabrication subsequent to the stage of fabrication illustrated in FIGS. 3A-3B. In the stage of fabrication shown in FIGS. 4A-4B, a directional push process 430 is performed to the IC device 300. In some embodiments, the directional push process 430 is a directional etching process. For example, the directional etching process may include a directional ion beam process, in which a beam of charged particles is directed toward an etching target in a high vacuum chamber. In the embodiment of FIGS. 4A-4B, the etching target is the portion of the top layer 363 (along with the protective layer 400 deposited thereon) in the openings 380-383 that is facing the Y-direction. In other words, the directional ion beam etching process is performed with a specific directionality: the beam of charged particles are projected toward the openings 380-383 in the Y-direction, but not in the X-direction.

In such an ion beam etching process, the portions of the protective layer 400 that are directly in the path of the beam of charged particles (e.g., the portions formed on the side surfaces of the top layer 363 facing the Y-direction) may be etched away first, and then the corresponding portions of the top layer 363 may then be etched by the beam of charged particles. Meanwhile, the portions of the protective layer 400 that are not directly in the path of the beam of charged particles (e.g., the portions formed on the side surfaces of the top layer 363 facing the X-direction) may be somewhat affected by the beam of charged particles, but they may not be completely etched away. In this manner, these portions of the protective layer 400 may protect the portions of the top layer 363 from being substantially etched in the X-direction. Even if these portions of the protective layer 400 are completely etched away eventually, this would have occurred much later in the process. By that point, the directional ion beam etching process would have already consumed a substantial amount of the portions of the top layer 363 facing the Y-direction. As such, the openings 380-383 can still be directionally enlarged in the Y-direction without being substantially enlarged in the X-direction.

The selective directional enlargement of the openings 380-383 can be manifested by a new dimension 440 of each of the openings 380-383 in the X-direction and a new dimension 441 of each of the openings 380-383 in the Y-direction. Due to the directionality in which the ion beams are applied, the end result is that the amount of etching of the openings 380-382 (and other similar openings) is greater in the Y-direction than the X-direction, which means that the new dimension 441 of each of the openings 380-382 is substantially larger than the previous dimension 391 of each of the openings 380-382 (before the directional push process 430 is performed), while the new dimension 440 of each of the openings 380-382 may be substantially similar to the previous dimension 390 of each of the openings 380-382 (before the directional push process 430 is performed). In some embodiments, each of the openings 380-382 is enlarged in the Y-direction by about at least 10 nanometers, meaning that the difference between the new dimension 441 and the previous dimension 391 is greater than or equal to about 10 nanometers. Meanwhile, the enlargement (if any) in the X-direction is less than about 0.5 nanometers, meaning that the difference between the new dimension 440 and the previous dimension 390 is less than about 0.5 nanometers. In some embodiments, the enlargement of any of the openings 380-382 in the Y-direction exceeds any potential enlargement of the corresponding opening in the X-direction by at least 10 nanometers, for example, by about 10˜14 nanometers. In other words, the difference between the dimensions 441 and 391 exceeds the difference between the dimensions 440 and 390 by about 10˜14 nanometers in these embodiments.

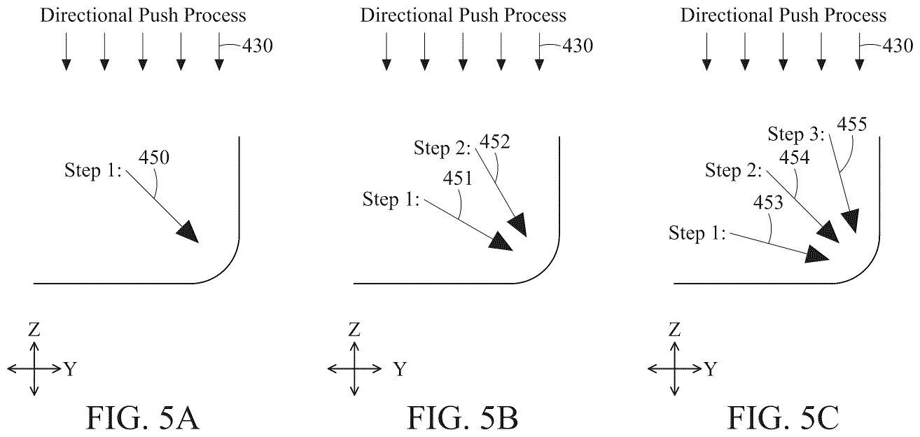

Note that the directional push process 430 may be performed with a directionality in the Z-direction vertically as well. In other words, the charged ion beam particles may be projected at a tilt angle, which may lead to the etching of the portions of the protective layer 400 in the Z-direction as well. Three example embodiments of this are illustrated in FIGS. 5A, 5B, and 5C, respectively.

Referring to FIG. 5A, the directional push process 430 is a one-step ion beam embodiment. According to the one-step ion beam embodiment, a single step ion beam application is used to perform the directional push process 430. This single step ion beam application is visually represented as a directional arrow 450 pointing toward the opening 381 (as an example opening in which the directional push process 430 is performed). The single step ion beam application is tilted, which is represented by the corresponding arrowing 450 having a Z-direction component and a Y-direction component (but substantially lacking an X-directional component). In other words, a tilt angle may be defined by the direction of the single step ion beam application (e.g., the arrow 450) and the Y-axis. In some embodiments, the tilt angle of the arrow 450 is in a range between about 40 degrees and about 55 degrees.

In comparison, the directional push process 430 in the embodiment of FIG. 5B is performed using a two-step ion beam application, where a first step of the ion beam application is visually represented by an arrow 451, and a second step of the ion beam application is visually represented by an arrow 452. The first step of the ion beam application and the second step of the ion beam application are performed with different tilt angles, which are represented by the different directions at which the arrows 451 and 452 are pointing. In some embodiments, the tilt angle of the arrow 451 is in a range between about 30 degrees and about 40 degrees, and the tilt angle of the arrow 452 is in a range between about 40 degrees and about 50 degrees.

Meanwhile, the directional push process 430 in the embodiment of FIG. 5C is performed using a three-step ion beam application, where a first step of the ion beam application is visually represented by an arrow 453, a second step of the ion beam application is visually represented by an arrow 454, and a third step of the ion beam application is visually represented by an arrow 455. The first step of the ion beam application, the second step of the ion beam application, and the third step of the ion beam application are performed with different tilt angles as well, which are represented by the different directions at which the arrows 453, 454, and 455 are pointing. In some embodiments, the tilt angle of the arrow 453 is in a range between about 30 degrees and about 40 degrees, the tilt angle of the arrow 454 is in a range between about 40 degrees and about 50 degrees, and the tilt angle of the arrow 455 is in a range between about 50 degrees and about 60 degrees.

In some embodiments, the type of material used to implement the ion beam process may also convey benefits. For example, Xenon (Xe) may be used as the ion beam gas to carry out the directional push process 430. Compared to other materials, Xenon may have a lower dosage. In some embodiments, the dosage of the Xenon in the ion beam process may be in a range between about 3.5E14 atoms/cm³ and about 7.5E14 atoms/cm³. Xenon may also have a lower cost compared to other candidates. Due to these factors, the directional push process 430 implemented using Xenon as the ion beam gas may be simple and cost effective. Nevertheless, it is understood that other materials such as He, Ne, Ar, N, or Rn may be used as the ion beam gas for the directional push process 430 in alternative embodiments as well.

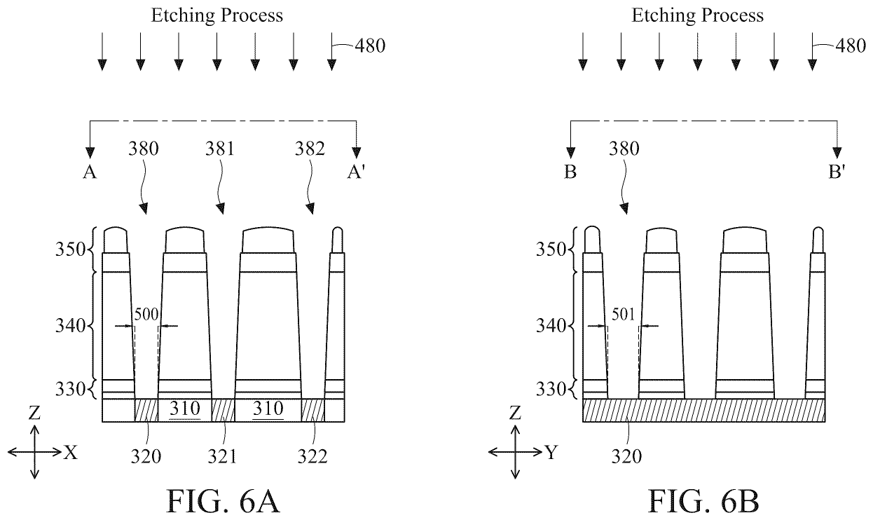

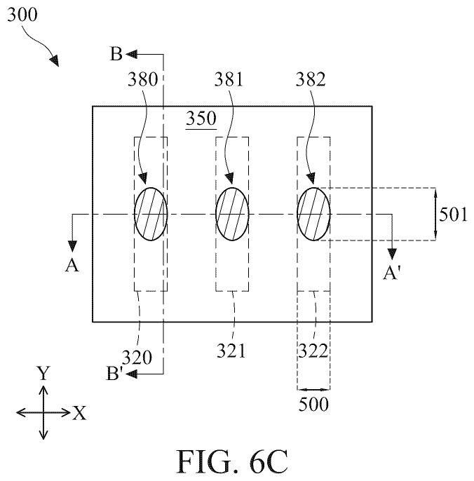

Referring now to FIGS. 6A-6C, diagrammatic fragmentary cross-sectional side views and a diagrammatic fragmentary planar top view of the IC device 300 are illustrated, at a stage of fabrication subsequent to the stage of fabrication illustrated in FIGS. 4A-4B. In more detail, FIG. 6A illustrates an X-cut cross-sectional side view of the IC device 300 taken along the cutline A-A′ (also shown in the planar top view of FIG. 6C), and FIG. 6B illustrates a Y-cut cross-sectional side view of the IC device 300 taken along the cutline B-B′ (also shown in the planar top view of FIG. 6C).

At the stage of fabrication shown in FIGS. 6A-6C, an etching process 480 is performed to the IC device 300. In some embodiments, the etching process 480 includes a dry etching process. The etching process 480 removes portions of the low-k film 340 and the etching-stop layer 330, while the mask layer 350 serves as a protective mask, such that the openings 380-382 are extended vertically downward in the Z-direction. The openings 380-382 are downwardly extended by the etching process 480 until portions of the interconnection elements 320-322 are exposed. At this point, the openings 380-382 may be referred to as via openings or via holes, since they will be subsequently filled by a conductive material to form the vias over the interconnection elements 320-322.

Note that due to the directional push process 430 discussed above, a dimension 500 (shown in FIGS. 6A and 6C) at the bottom of each of the openings 380-382 in the X-direction is smaller than a dimension 501 (shown in FIGS. 6B and 6C) at the bottom of each of the openings 380-382 in the Y-direction. In some embodiments, a ratio between the dimension 501 and the dimension 500 is greater than 1:1, for example, greater than 1.2:1. In some embodiments, the dimension 501 is greater than the dimension 500 by at least about 10˜14 nanometers. It is understood that whatever remnants of protective layer 400 that may have existed before the etching processes 480 may be removed by the etching process 480, or by another suitable etching process before the etching process 480 is performed.

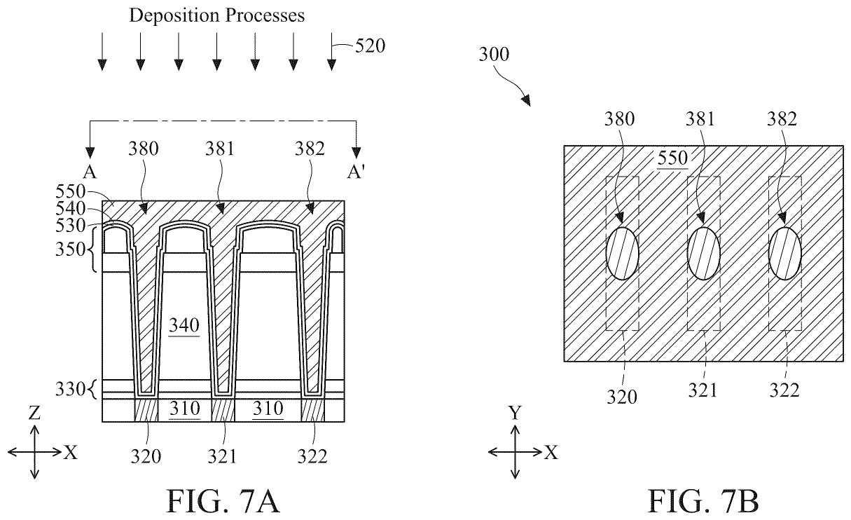

Referring now to FIGS. 7A-7B, a diagrammatic fragmentary cross-sectional side views and a diagrammatic fragmentary planar top view of the IC device 300 are illustrated, respectively, at a stage of fabrication subsequent to the stage of fabrication illustrated in FIGS. 6A-6C. Again, the cross-sectional side view of FIG. 7A is an X-cut taken along the cutline A-A′ that is also shown in the planar top view of FIG. 7B. In this stage of fabrication, one or more deposition processes 520 may be performed to deposit a barrier layer 530 and a seed layer 540 in the openings 380-382. For example, the barrier layer 530 may be deposited on the exposed surface surfaces of the IC device 300, including on the upper surfaces of the interconnection elements 320-322 and on the side surfaces of the low-k film 340. The barrier layer 530 may include a material configured to reduce undesirable diffusion between the conductive vias (to be formed) and the rest of the IC device 300. The seed layer 540 may be formed on the barrier layer 530 and may include a conductive material (e.g., copper) configured to facilitate the formation of a conductive material 550. For example, a copper electroplating process may be performed (either as a part of the deposition processes 520 or after the deposition processes 520) to fill the openings 380-382 with copper as the conductive material 550. In such a process, the seed layer 540 facilitates the electroplating formation of the conductive material 550 in the openings 380-382. In other embodiments, the seed layer 540 and the conductive material 550 may include other suitable materials.

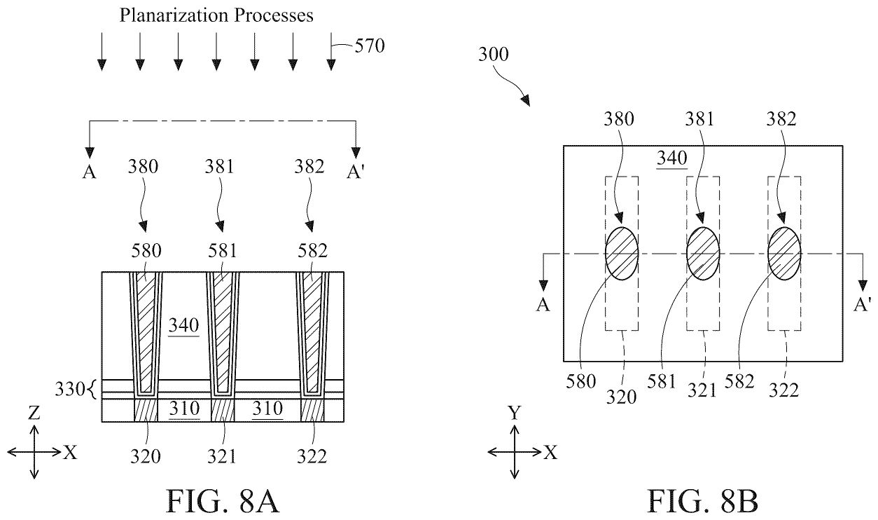

Referring now to FIGS. 8A-8B, a diagrammatic fragmentary cross-sectional side views and a diagrammatic fragmentary planar top view of the IC device 300 are illustrated, respectively, at a stage of fabrication subsequent to the stage of fabrication illustrated in FIGS. 7A-7B. Again, the cross-sectional side view of FIG. 8A is an X-cut taken along the cutline A-A′ that is also shown in the planar top view of FIG. 8B. A planarization process 570 is performed to the IC device 300. In some embodiments, the planarization process 570 includes a chemical mechanical polishing (CMP) process. The CMP process uses chemical etching and mechanical grinding to remove portions of the IC device 300 until the upper surfaces of the conductive material 550 filling the openings 380-382 are substantially coplanar with the upper surfaces of the low-k film 340. At this point, conductive vias 580-582 are formed by the portions of the conductive material 550 filling the openings 380-382, respectively.

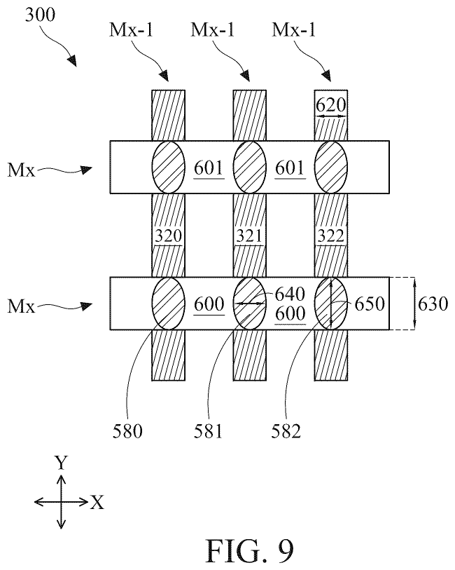

Additional fabrication processes may be performed to complete the fabrication of the IC device 300. For example, additional interconnection elements from additional interconnect layers of the multi-layer interconnect structure may be formed over the portion of the IC device 300 shown in FIG. 8A. One example is illustrated in FIG. 9, which is a diagrammatic fragmentary planar top view of the IC device 300, at a stage of fabrication subsequent to the stage of fabrication illustrated in FIGS. 8A-8B. As shown in FIG. 9, interconnection elements 600 and 601 are formed directly over the conductive vias 580-582. The interconnection elements 600 and 601 are formed as a part of an interconnect layer M_{X}, which is one interconnect layer above the interconnect layer M_{X-1} that includes the interconnection elements 320-322. Note that the interconnect layer M_{X-1} and the interconnect layer M_{X} can be any two vertically adjacent interconnect layers. For example, the interconnect layer M_{X-1} may be a metal-0 layer, while the interconnect layer M_{X} may be a metal-1 layer. Alternatively, the interconnect layer M_{X-1} may be a metal-3 layer, while the interconnect layer M_{X} may be a metal-4 layer.

Regardless of the exact interconnect layers to which the interconnection elements 320-322 and/or the interconnection elements 600-601 belong, it is understood that the interconnect layer M_{X-1} and the interconnect layer M_{X} may be interconnected by the conductive vias 580-582. For example, since the conductive via 580 is located in an overlap area between the interconnection element 320 and the interconnection element 600 in the planar top view, the conductive via 580 is electrically interconnected to both the interconnection element 320 and the interconnection element 600, such that a bottom surface (in the vertical Z-direction) of the conductive via 580 is in direct contact with the top surface of the interconnection element 320, and a top surface (in the vertical Z-direction) of the conductive via 580 is in direct contact with the bottom surface of the interconnection element 600.

In some embodiments, the interconnection elements 320-322 have widths that are different from the interconnection elements 600-601. For example, the interconnection elements 320-322 may each have a width 620 measured in the X-direction, while the interconnection elements 600-601 may each have a width 630 that is measured in the Y-direction, where the width 630 is greater than the width 620. In some embodiments, the width 620 may be in a range between about 0.01 microns and about 0.36 microns, and the width 630 may be in a range between about 0.01 microns and about 0.36 microns, but a ratio between the width 630 and the width 620 is greater than about 1:1. In other embodiments, the width 620 and the width 630 may be substantially equal to one another, and the ratio between the width 620 and the width 630 may be about 1:1.

As discussed above, the directional push process 430 of FIGS. 4A-4B of the present disclosure is performed to selectively enlarge the openings 380-382 in the Y-direction, but not (or at least not as much) in the X-direction. Since the conductive vias 580-582 are formed by filling the openings 380-382, an inherent result of the directional push process 430 is that the conductive vias 580-582 may each have a larger dimension in the Y-direction than in the X-direction. For example, the conductive vias 580-582 may each have a maximum dimension 640 measured in the X-direction, as well as a maximum dimension 650 measured in the Y-direction. In some embodiments, the maximum dimension 640 and the maximum dimension 650 may each be in a range from about 10 nanometers and about 60 nanometers. Had the directional push process 430 discussed above not been performed, the maximum dimension 640 and the maximum dimension 640 may be substantially similar to one another in value. However, as an inherent result of the openings 380-382 having been selectively enlarged in the Y-direction, the maximum dimension 650 of the conductive vias 580-582 is greater than the maximum dimension 640 of the conductive vias 580-582. For example, a ratio between the maximum dimension 650 and the maximum dimension 640 is greater than about 1:1. In some embodiments, the ratio between the maximum dimension 650 and the maximum dimension 640 is greater than about 1.2:1. In other words, the maximum dimension 650 may be larger than the maximum dimension 640 by about 20% or more. In some embodiments, a difference between the maximum dimension 650 and the maximum dimension 640 is in a range between about 10 nanometers and about 14 nanometers. Due to this difference in the dimensions 640 and 650, each the of the conductive vias 580-582 may exhibit an oval-like shape in the planar top view in the embodiment shown in FIG. 9. However, it is understood that other top view shapes are also possible for the conductive vias 580-582 in other embodiments.

In any case, due to the conductive vias 580-582 each being selectively enlarged in the Y-direction, but little to none in the X-direction, the conductive vias 580-582 can achieve larger sizes (e.g., larger contact surface area at an interface with the interconnection elements 600-601), which helps to reduce the parasitic resistance of the conductive vias 580-582. Meanwhile, the little-to-no enlargement of the conductive vias 580-582 in the X-direction means that each conductive via 580-582 is still sufficiently spaced apart from adjacently located interconnection elements 320-322, which helps to minimize a potential electrical shorting risk (e.g., a tiger tooth type of electrical shorting where a bottom of the conductive via shorts into an adjacent interconnection element).

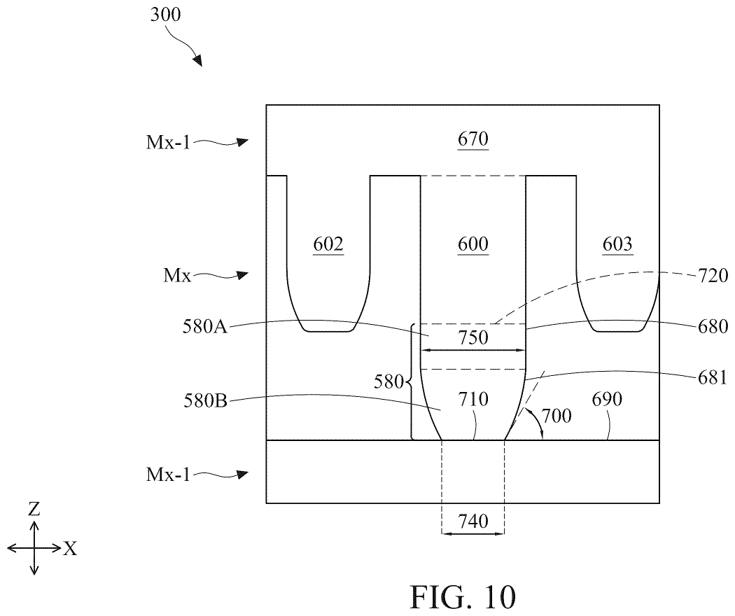

FIG. 10 is another diagrammatic fragmentary cross-sectional side view of a portion of the IC device 300 to illustrate additional aspects of the present disclosure. Specifically, FIG. 10 is a Y-cut view of the IC device 300, which is taken along a vertical plane defined by the Y-direction horizontally and the Z-direction vertically. In the Y-cut view of FIG. 10, the IC device 300 includes the interconnection element 320 from the M_{X-1} interconnect layer, the conductive via 580 disposed directly on the interconnection element 320, the interconnection element 600 disposed directly on the conductive via 580, and another interconnection element 670 of an M_{X+1} interconnect layer disposed directly on the interconnection element 600. The interconnect layer M_{X} also includes additional interconnection elements 602 and 603, but they are not disposed directly on any conductive vias in the cross-sectional view of FIG. 10. In other words, the interconnection elements 320 and 670 may be different metal lines from different interconnect layers M_{X-1} and M_{X+1}, but they each extend in the Y-direction horizontally, while the interconnection elements 600 and 602-603 may be different metal lines from yet another interconnect layer (M_{X}) disposed in between the interconnect layers M_{X-1} and M_{X+1}, but they each extend in the X-direction horizontally.

As discussed above, the conductive via 580 may be formed by filling the opening 380 after the directional push process 430, such that it is selectively enlarged in the Y-direction but not as much in the X-direction. As yet another inherent result of the directional push process 430, the conductive via 580 may have other physical characteristics that set itself apart from other conductive vias formed by conventional methods. For example, the conductive via 580 may include an upper segment 580A and a lower segment 580B disposed directly below the upper segment 580A. In other words, the upper segment 580A is disposed directly below the interconnection element 600, and the lower segment 580B is disposed directly above the interconnection element 320.

As shown in FIG. 10, a side surface 680 of the upper segment 580A is more vertically oriented than a side surface 681 of the lower segment 580B. For example, whereas the side surface 680 extends substantially along the Z-direction vertically, the side surface 681 is slanted (i.e., it has both a Z-directional component and a Y-directional component). In this manner, the side surface 681 and an upper surface 690 (which may extend substantially in the Y-direction horizontally) of the interconnection element 320 may define a slant angle 700. In some embodiments, the slant angle 700 is in a range between about 60 degrees and about 85 degrees. Compared to conductive vias formed by other methods, the slant angle 700 may be greater in value. Stated differently, the conductive vias formed by other methods may also have a slant angle, but that slant angle may be smaller, which means that the conductive vias formed by other methods may have more slanted side surfaces. One reason the slant angle 700 is less slanted is because the directional push process 430 effectively “pushes” the sidewalls of the opening 380 (which is filled by the conductive via 580) outwards in the Y-direction, which then leads to a less slanted profile.

Another unique physical characteristic of the conductive via 580 as an inherent result of the fabrication processes herein being performed is that a bottom surface 710 of the conductive via 580 is relatively large compared to a top surface 720 of the conductive via 580. As shown in FIG. 10, the bottom surface 710 of the conductive via 580 has a dimension 740 in the Y-direction, and the top surface 720 of the conductive via 580 has a dimension 750 in the Y-direction. The dimension 750 may be larger than the dimension 740, but not by a substantial amount. In some embodiments, a ratio between the dimension 750 and the dimension 740 is in a range between about 1.1:1 and about 1.7:1. Again, the relatively large dimension 740 of the bottom surface 710 of the conductive via 580 is also attributable to the directional push process 430 having been performed, which helps to push the side surfaces of the conductive via 580 laterally outwards in the Y-direction. In contrast, conductive vias formed by other fabrication processes may have substantially smaller bottom surfaces relative to their top surfaces, since their side surfaces would not have been expanded in the Y-direction.

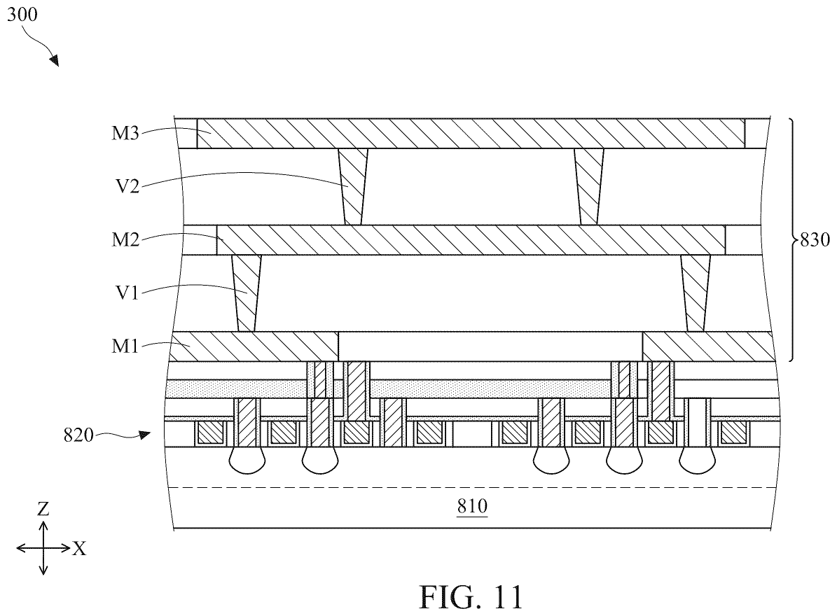

FIG. 11 is a diagrammatic fragmentary cross-sectional side view of an embodiment of the IC device 300 as an X-cut in an example context. In more detail, the IC device 300 includes a substrate 810, which may be an embodiment of the substrate 110 discussed above. A plurality of transistors 820, such as the FinFET or GAA devices discussed above, may be formed in or on the substrate 810. An interconnect structure 830 is formed over the transistors 820 and provides electrical connectivity for the transistors 820. The interconnect structure 830 includes a plurality of interconnect layers, such as interconnect layers M1, M2, and M3. The interconnect structure 830 also includes a plurality of conductive vias to electrically couple the interconnect layers together. For example, a conductive via V1 electrically couples together interconnection features of the interconnect layers M1 and M2, and a conductive via V2 electrically couples together interconnection features of the interconnect layers M2 and M3. The interconnection features may include metal lines (e.g., in the form of rectangular strips that extend in a horizontal direction). In some embodiments, a thickness of a bottommost one of the plurality of metal lines (e.g., located in a bottommost interconnect layer) is less than a thickness of at least one of the plurality of metal lines disposed above the bottommost one of the plurality of metal lines, and at least one of the plurality of metal lines comprises a curved end portion. Using FIG. 10 as an example, at least one of the interconnection elements 320, 600, or 670 comprises a curved end portion. In addition, at least two metal lines in the interconnect layers extend along different directions. For example, a metal line in an M1 layer may extend in one horizontal direction, while a metal line in an M2 layer (e.g., disposed immediately above the M1 layer) may extend in another horizontal direction different from (e.g., perpendicular to) the horizontal direction in which the metal line in M1 layer extends. Using FIG. 10 as an example again, the interconnection element 320 in the M_{X-1} layer and the interconnection element 670 in the M_{X+1} layer each extend in the Y-direction, whereas the interconnection element 600 in the M_{X} layer extends in the X-direction. According to the various aspects of the present disclosure, either the conductive vias V1 or V2, or both, may be implemented at least in part using the directional push process 430 discussed above, such that the conductive vias V1 or V2 may be selectively enlarged in one horizontal direction but not the other.

It is also understood that the direction in which the conductive via V1 is enlarged may be different than the direction in which the conductive via V2 is enlarged. For example, in some embodiments, the conductive via V1 may be enlarged in the X-direction, but not in the Y-direction, while the conductive via V2 may be enlarged in the Y-direction, but not in the X-direction. In some other embodiments, the conductive via V1 may be enlarged in the Y-direction, but not in the X-direction, while the conductive via V2 may be enlarged in the X-direction, but not in the Y-direction. Furthermore, although only three interconnect layers M1-M3 are illustrated in the embodiment of FIG. 11, this is merely done for the sake of simplicity. It is understood that the interconnect structure 830 may include many more interconnect layers (or fewer) in other embodiments, and that the selective enlargement of the conductive vias may apply to any conductive via interconnect any two adjacent (in the vertical direction) interconnect layers in the interconnect structure 830.

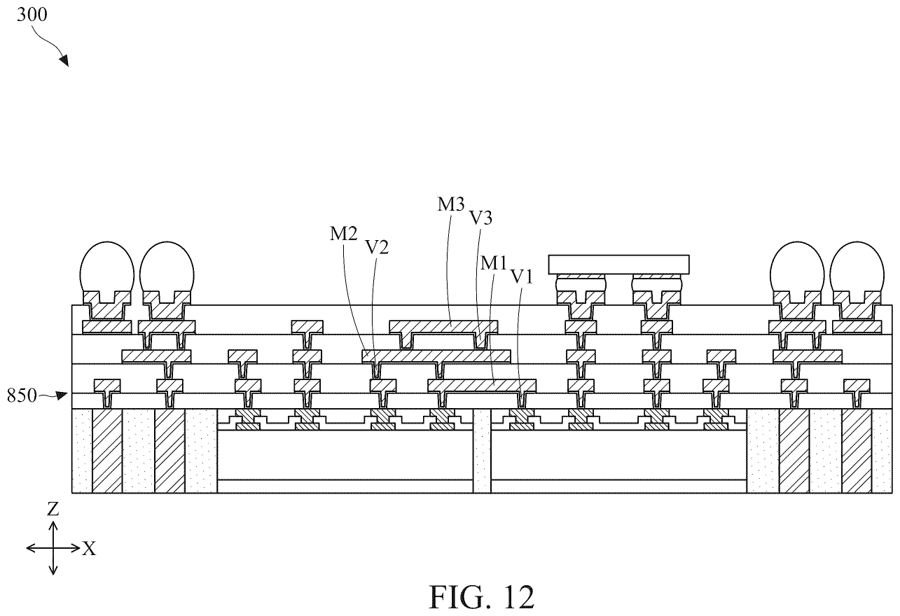

FIG. 12 is a diagrammatic fragmentary cross-sectional side view of an embodiment of the IC device 300 as an X-cut according to an example context. In this example context, the IC device 300 is a part of an IC package, which may include a plurality of different types of microelectronic components, such as transistors, resistors, inductors, capacitors, etc. The IC package may also include a redistribution layer (RDL) structure 850, which includes a plurality of metallization layers, such as M1, M2, M3, (e.g., copper-based metallization layers) that can be used to facilitate electrical routing (and/or heat dissipation) for the IC package. For example, another type of IC device may be formed over the RDL structure 850. In some embodiments, the IC device formed over the RDL structure 850 may be an Integrated Passive Device (IPD), which is an IC containing passive components such as capacitors, inductors, or resistors. The IPD may or may not contain active devices such as transistors. In other embodiments, the IC device formed over the RDL structure 850 may include ICs containing active electrical circuitry (e.g., with transistors). In any case, the RDL structure 850 may include a plurality of conductive vias, such as conductive vias V1, V2, and V3, for providing electrical connectivity between the various metallization layers M1-M3. Any one of the conductive vias V1-V3 of the RDL structure 850 may be implemented using various aspects of the present disclosure discussed above, for example, by selectively enlarging the conductive vias V1/V2/V3 in a specified horizontal direction, but not in another horizontal direction perpendicular to the specified horizontal direction.

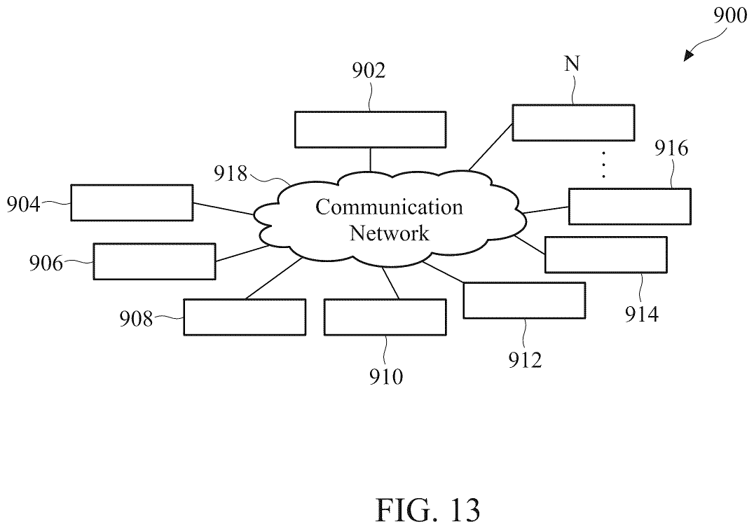

FIG. 13 illustrates an integrated circuit fabrication system 900 that may be used to perform the fabrication processes discussed above (e.g., the directional push process 430 and/or the various deposition and etching processes) according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes to define the gate spacers of an SRAM device; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

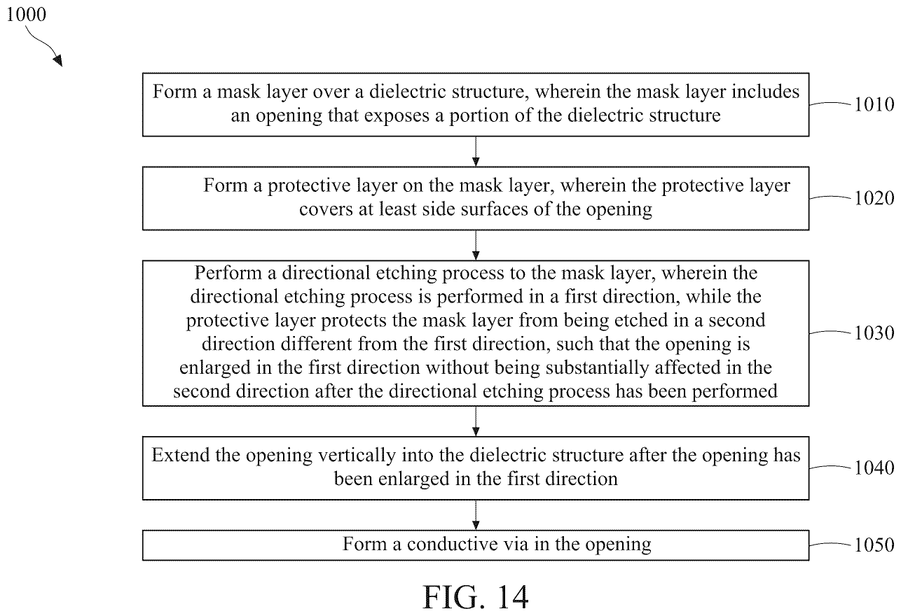

FIG. 14 is a flowchart of a method 1000 of bonding IC devices according to various aspects of the present disclosure. The method 1000 includes a step 1010 to form a mask layer over a dielectric structure. The mask layer includes an opening that exposes a portion of the dielectric structure.

The method 1000 includes a step 1020 to form a protective layer on the mask layer. The protective layer covers at least side surfaces of the opening. In some embodiments, the forming the protective layer includes depositing silicon oxide, silicon nitride, silicon oxynitride, aluminum oxide, or tin oxide as the protective layer. In some embodiments, a thickness of the protective layer is formed to be in a range between about 5 angstroms and about 20 angstroms.

The method 1000 includes a step 1030 performed after the forming of the protective layer in step 1020. The step 1030 performs a directional etching process to the mask layer, wherein the directional etching process is performed in a first direction, while the protective layer protects the mask layer from being etched in a second direction different from the first direction, such that the opening is enlarged in the first direction without being substantially affected in the second direction after the directional etching process has been performed. After the directional etching process has been performed, a difference between a dimension of the opening in the first direction and a dimension of the opening in the second direction is in a range between about 10 nanometers and about 14 nanometers.

In some embodiments, the directional etching process includes performing a directional ion beam process. In some embodiments, the directional ion beam process is performed using a single step ion beam process, and the single step ion beam process is performed at a tilt angle in a range between about 40 degrees and about 55 degrees. In some embodiments, the directional ion beam process is performed using a two-step ion beam process, a first step of the two-step ion beam process is performed at a tilt angle in a range between about 30 degrees and about 40 degrees, and a second step of the two-step ion beam process is performed at a tilt angle in a range between about 40 degrees and about 50 degrees. In some embodiments, the directional ion beam process is performed using a three-step ion beam process, a first step of the three-step ion beam process is performed at a tilt angle in a range between about 30 degrees and about 40 degrees, a second step of the three-step ion beam process is performed at a tilt angle in a range between about 40 degrees and about 50 degrees, and a third step of the three-step ion beam process is performed at a tilt angle in a range between about 50 degrees and about 60 degrees. In some embodiments, the directional ion beam process is performed using Xe as an ion beam gas. In some embodiments, the directional ion beam process is performed using a dosage in a range between about 3.5E14 atoms/cm³ and about 7.5E14 atoms/cm³.

The method 1000 includes a step 1040 to extend the opening vertically into the dielectric structure after the opening has been enlarged in the first direction.

The method 1000 includes a step 1050 to form a conductive via in the opening.

It is understood that the method 1000 may include further steps performed before, during, or after the steps 1010-1050. For example, the method 1000 may include a step of: before the forming of the mask layer, forming a first interconnection element of a first interconnect layer of a multi-layer interconnect structure. The extending (of step 1040) of the opening directly expose an upper surface of the first interconnection element. As another example, the method 1000 may include a step of: after the forming of the conductive via, forming a second interconnection element of a second interconnect layer of the multi-layer interconnect structure. The second interconnection element is formed directly over the conductive via. For reasons of simplicity, other additional steps are not discussed herein in detail.

In summary, the present disclosure involves selectively enlarging a conductive via in a specified horizontal direction. For example, a directional ion beam process may be performed to an opening defined by a mask layer, such that the opening is enlarged more in the specified horizontal direction than in another horizontal direction perpendicular to the specified horizontal direction. The opening is used to etch a via hole in a dielectric structure below, and the via hole is filled with a conductive material to form the conductive via. Since the opening having been selectively enlarged in the specified horizontal direction, the conductive via formed in the opening will inherit the shape of the opening and will have an enlarged dimension in the specified horizontal direction as well.

The embodiments of the present disclosure offer advantages over conventional IC devices. It is understood, however, that other embodiments may offer additional advantages, and not all advantages are necessarily disclosed herein, and that no particular advantage is required for all embodiments. One advantage is the reduction in parasitic performance. In more detail, as IC devices continue to get scaled down, the size of the conductive via becomes smaller as well, which may increase the parasitic resistance associated with the conductive via. Enlarging the conductive via may reduce its parasitic resistance, but doing so indiscriminately may elevate the electrical shorting risks between the conductive via and adjacently located conductive components (e.g., a metal line located nearby). According to the various aspects of the present disclosure, the directional ion beam process is performed such that the conductive via is enlarged in the desired horizontal direction, which may help to reduce the parasitic reduce of the conductive via. Meanwhile, the conductive via is not enlarged at all, or much less, in the other horizontal direction where electrical shorting with nearby devices may be a concern. In this manner, the overall size (e.g., contact surface area) of the conductive via can be enlarged to achieve reduced parasitic resistance, but without increasing the electrical shorting risks involving the conductive via. As a result, IC device performance such as speed or power dissipation may improve, and the yield or lifespan of the IC device may also improve. Another advantage pertains to the use of Xe as a component of the ion beam, since Xe may be applied with a relatively low dosage and is therefore cheap to implement. Other advantages include compatibility with existing fabrication processes and the ease and low cost of implementation.

One aspect of the present disclosure pertains to a method. According to the method, a mask layer is formed over a dielectric structure. The mask layer includes an opening that exposes a portion of the dielectric structure. A protective layer is formed on the mask layer. The protective layer covers at least side surfaces of the opening. After the forming of the protective layer, a directional etching process is performed to the mask layer. The directional etching process is performed in a first direction, while the protective layer protects the mask layer from being etched in a second direction different from the first direction, such that the opening is enlarged in the first direction without being substantially affected in the second direction after the directional etching process has been performed. The opening is extended vertically into the dielectric structure after the opening has been enlarged in the first direction. A conductive via is formed in the opening.

Another aspect of the present disclosure pertains to a structure. The structure includes a first interconnection element disposed in a first interconnect layer of a multi-layer interconnect structure. The first interconnection element extends in a first horizontal direction in a top view. The structure includes a second interconnection element disposed in a second interconnect layer of the multi-layer interconnect structure. The second interconnection element extends in a second horizontal direction different from the first horizontal direction in the top view. The structure includes a conductive via that is disposed at an intersection between the first interconnection element and the second interconnection element in the top view and vertically between the first interconnection element and the second interconnection element in a cross-sectional side view. The conductive via has a first dimension in the first horizontal direction in the top view and a second dimension in the second horizontal direction in the top view. The first dimension is greater than the second dimension.

Yet another aspect of the present disclosure pertains to an IC device. The IC device includes a first metal component that extends in a first horizontal direction in a top view. The first metal component has a first dimension measured in a second horizontal direction in the top view. The IC device includes a conductive via disposed on the first metal component in a cross-sectional side view defined by a vertical direction and the first horizontal direction. A side surface of the conductive via and an upper surface of the first metal component define an angle that is in a range between about 60 degrees and about 85 degrees. A dimension of the conductive via in the first horizontal direction is larger than a dimension of the conductive via in the second horizontal direction. The IC device includes a second metal component disposed over the conductive via in the cross-sectional side view. The second metal component extends in the second horizontal direction in the top view. The second metal component has a second dimension measured in the first horizontal direction in the top view. The second dimension is greater than the first dimension.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a mask layer over a dielectric structure, wherein the mask layer includes an opening that exposes a portion of the dielectric structure;
forming a protective layer on the mask layer, wherein the protective layer covers at least side surfaces of the opening; and
after the forming of the protective layer, performing a directional etching process to the mask layer, wherein the directional etching process is performed in a first direction, while the protective layer protects the mask layer from being etched in a second direction different from the first direction, such that the opening is enlarged in the first direction without being substantially affected in the second direction after the directional etching process has been performed;
extending the opening vertically into the dielectric structure after the opening has been enlarged in the first direction; and
forming a conductive via in the opening.

2. The method of claim 1, wherein the forming the protective layer includes depositing silicon oxide, silicon nitride, silicon oxynitride, aluminum oxide, or tin oxide as the protective layer.

3. The method of claim 1, further comprising:
before the forming of the mask layer, forming a first interconnection element of a first interconnect layer of a multi-layer interconnect structure, wherein the extending of the opening directly expose an upper surface of the first interconnection element; and
after the forming of the conductive via, forming a second interconnection element of a second interconnect layer of the multi-layer interconnect structure, wherein the second interconnection element is formed directly over the conductive via.

4. The method of claim 3, wherein the forming the first interconnection element and the forming the second interconnection element are performed such that:
the first interconnection element and the second interconnection element extend in different horizontal directions;
the second interconnection element has a greater thickness than the first interconnection element; or
at least one of the first interconnection element and the second interconnection element comprises a curved end portion.

5. The method of claim 1, wherein after the directional etching process has been performed, a difference between a dimension of the opening in the first direction and a dimension of the opening in the second direction is in a range between about 10 nanometers and about 14 nanometers.

6. The method of claim 1, wherein the performing the directional etching process includes performing a directional ion beam process.

7. The method of claim 6, wherein:
the directional ion beam process is performed using a single step ion beam process; and
the single step ion beam process is performed at a tilt angle in a range between about 40 degrees and about 55 degrees.

8. The method of claim 6, wherein:
the directional ion beam process is performed using a two-step ion beam process;
a first step of the two-step ion beam process is performed at a tilt angle in a range between about 30 degrees and about 40 degrees; and
a second step of the two-step ion beam process is performed at a tilt angle in a range between about 40 degrees and about 50 degrees.

9. The method of claim 6, wherein:
the directional ion beam process is performed using a three-step ion beam process;
a first step of the three-step ion beam process is performed at a tilt angle in a range between about 30 degrees and about 40 degrees;
a second step of the three-step ion beam process is performed at a tilt angle in a range between about 40 degrees and about 50 degrees; and
a third step of the three-step ion beam process is performed at a tilt angle in a range between about 50 degrees and about 60 degrees.

10. The method of claim 6, wherein the directional ion beam process is performed using Xe as an ion beam gas.

11. The method of claim 6, wherein the directional ion beam process is performed using a dosage in a range between about 3.5E14 atoms/cm³ and about 7.5E14 atoms/cm³.

12. The method of claim 1, wherein a thickness of the protective layer is formed to be in a range between about 5 angstroms and about 20 angstroms.

13. A method, comprising:
forming a mask layer over a dielectric structure, wherein the mask layer includes an opening that exposes a portion of the dielectric structure;
forming a protective layer on the mask layer, wherein the protective layer covers at least side surfaces of the opening and contains silicon oxide, silicon nitride, silicon oxynitride, aluminum oxide, or tin; and
after the forming of the protective layer, performing a directional ion beam process to the mask layer, wherein the directional ion beam process is performed in a first direction in one or more steps and has a tilt angle in a range between about 30 degrees and about 60 degrees, while the protective layer protects the mask layer from being etched in a second direction different from the first direction, such that the opening is enlarged more in the first direction than in the second direction after the directional ion beam process has been performed;
etching the opening vertically into the dielectric structure after the directional ion beam process has been performed; and
filling the opening with a conductive via.

14. The method of claim 13, further comprising:
before the forming of the mask layer, forming a first metal line of a first metal layer of a multi-layer interconnect structure, wherein the opening is etched such an upper surface of the first metal line is exposed; and
after the filling, forming a second metal line of a second metal layer of the multi-layer interconnect structure, wherein the second metal line is formed directly over the conductive via;
wherein:
the first metal line and the second metal line extend in different horizontal directions;
the second metal line has a greater thickness than the first metal line; or
at least one of the first metal line and the second metal line comprises a curved end portion.

15. The method of claim 13, wherein the directional ion beam process is performed using Xe as an ion beam gas.

16. The method of claim 13, wherein the directional ion beam process is performed using a dosage in a range between about 3.5E14 atoms/cm³ and about 7.5E14 atoms/cm³.

17. An integrated circuit (IC) device, comprising:
a first metal component that extends in a first horizontal direction in a top view, wherein the first metal component has a first dimension measured in a second horizontal direction in the top view;
a conductive via disposed on the first metal component in a cross-sectional side view defined by a vertical direction and the first horizontal direction, wherein a side surface of the conductive via and an upper surface of the first metal component define an angle that is in a range between about 60 degrees and about 85 degrees, and wherein a dimension of the conductive via in the first horizontal direction is larger than a dimension of the conductive via in the second horizontal direction; and
a second metal component disposed over the conductive via in the cross-sectional side view, wherein the second metal component extends in the second horizontal direction in the top view, wherein the second metal component has a second dimension measured in the first horizontal direction in the top view, and wherein the second dimension is greater than the first dimension.

18. The IC device of claim 17, wherein at least one of the first metal component and the second metal component comprises a curved end portion.

19. The IC device of claim 17, wherein the dimension of the conductive via in the first horizontal direction is larger than the dimension of the conductive via in the second horizontal direction by about 10 nanometers and about 14 nanometers.

20. The IC device of claim 17, wherein:
the conductive via includes an upper segment and a lower segment disposed below the upper segment in the cross-sectional side view;
the upper segment has a substantially more vertical side surface than the lower segment in the cross-sectional side view; and
the angle is defined by the side surface of the upper segment and the upper surface of the first metal component.
